(19) United States
(12) Patent Application Publication
(10) Pub. No.: US 2026/0314030 A1
(43) Pub. Date: Oct. 8, 2026

(54) SEMICONDUCTOR DEVICE WITH IMPROVED GATE STRUCTUREAND METHODS OF FABRICATION THEREOF

(71) Applicant: TAIWAN SEMICONDUCTOR MANUFACTURING COMPANY, LTD., Hsinchu (TW)

(72) Inventors: Shih-Hsun YU, Taoyuan (TW); Yung-Chien HUANG, Kaohsiung (TW); Tai-Wei HWANG, Kinmen (TW); Da-Yuan LEE, Hsinchu (TW); Chi On CHUI, Hsinchu (TW)

(21) Appl. No.: 19/170,394

(22) Filed: Apr. 4, 2025

(51) Int. Cl. H10D 84/01; H10D 84/85

(52) U.S. Cl. CPC H10D 84/0177; H10D 84/851

(57) ABSTRACT

A semiconductor device structure is provided. The semiconductor device structure comprises a first stack of channels of a p-type field effect transistor (PFET) and a second stack of channels of an n-type field effect transistors (NFET) adjacent to the PFET. A gate dielectric layer is formed on each channel of the PFET and the NFET. A first metal gate layer is formed on the gate dielectric layer of the PFET. A second metal gate layer is formed on the gate dielectric layer of the NFET. The second metal gate layer comprises one or more types of aluminum compounds filling at least a central portion of a channel-to-channel space between each pair of immediately adjacent channels of the NFET.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge. For example, transistors using nanowire channels have been proposed to achieve increased device density, greater carrier mobility and drive current in a device. As device size reduces, there is a continuous need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of a semiconductor device structure in accordance with some embodiments.

FIGS. 7-12 are cross-sectional views showing the processes of forming metal gate material in an NFET of the semiconductor device structure as shown in FIGS. 1-6 in accordance with some embodiments.

FIGS. 13 and 14 are electric energy loss (EEL) spectra showing Ti distribution and Al distribution of a metal gate layer around N-channels of an NFET and a PFET, respectively, in accordance with some embodiments.

FIG. 15 shows a method for forming the semiconductor device structure as shown in FIGS. 1-12 in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fabrication process of a gate in a metal-oxide semiconductor field effect transistor (MOSFET) includes NFET/PEET metal film deposition. The conformalities of the metal films have been an issue from fabrication of a FinFET to fabrication of a Gate-All-Around (GAA) channel architecture. Particularly, within a limited space between two adjacent channels, metal films may merge earlier at the openings at the edges of the channels to hinder the precursor to diffuse into the inner sheet area, that is, a central portion of the space between the channels. As a result, voids or seams may be formed in the central portion of the space. Formation of voids and seams causes a thickness loading issue both vertical and lateral directions that may affect the device characteristics or performances. For example, the stability of the threshold voltage V_{T} may be impacted. In an N2/N3/N4/N5 GAA device, formation of the voids and seams in the metal film formed between the adjacent channels becomes more significant. Therefore, a semiconductor device that has improved gap filling for metal film around a channel region is desirable.

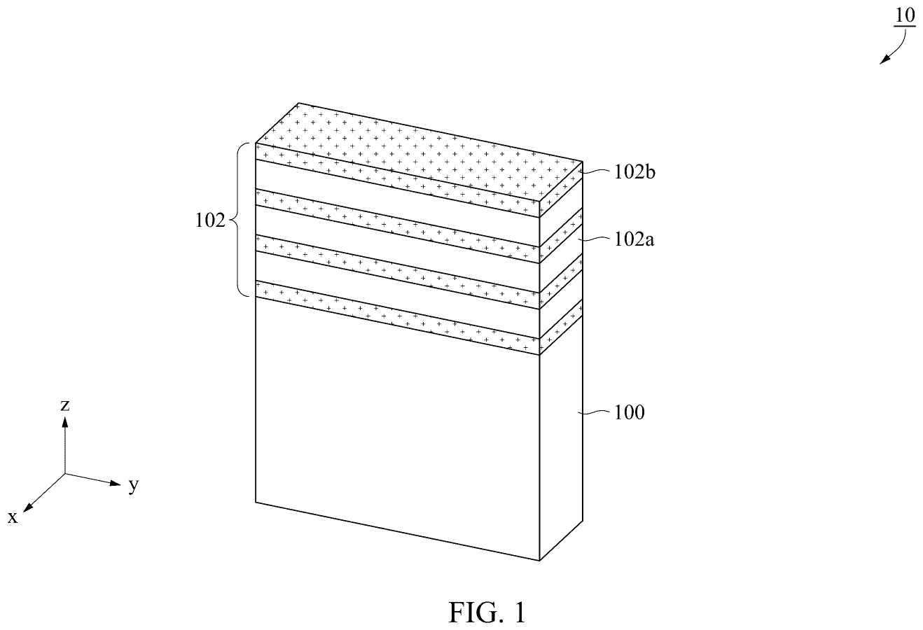

FIGS. 1 to 12 show exemplary processes for manufacturing a semiconductor device structure 100 according to embodiments of the present disclosure. It is understood that additional operations can be provided before, during, and after processes shown by FIGS. 1 to 12, and some of the operations described below can be replaced or eliminated, for additional embodiments of the method. The order of the operations/processes is not limiting and may be interchangeable. While the embodiments of this disclosure are discussed with respect to FETs with nanoscale, implementations of some aspects of the present disclosure may be used in other processes and/or in other devices, such as planar FETs, FinFETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

FIGS. 1 to 6 are perspective views showing various stages for manufacturing a GAA device. In FIG. 1, a substrate 100 is provided. According to one embodiment, the substrate 100 may be a semiconductor substrate. In some embodiments, the substrate 100 includes a single crystalline semiconductor layer on at least the surface of the substrate 100. The substrate 100 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In this embodiment, the substrate 100 is made of Si. In some embodiments, the substrate 100 is a silicon-on-insulator (SOI) substrate, which includes an insulating layer (not shown) disposed between two silicon layers. In one aspect, the insulating layer is an oxide.

One or more buffer layers (not shown) may be formed on the surface of the substrate 100. The buffer layers can serve to gradually change the lattice constant from that of the substrate to that of the source/drain (S/D) regions to be grown on the substrate 100. The buffer layers may be formed from epitaxially grown single crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaN, and InP. In one embodiment, the substrate 100 includes SiGe buffer layers epitaxially grown on the silicon substrate 100. The germanium concentration of the SiGe buffer layers may increase from 30 atomic percent germanium for the bottom-most buffer layer to 70 atomic percent germanium for the top-most buffer layer. The substrate 100 may include various regions that have been suitably doped with impurities (e.g., p-type or n-type impurities). The dopants are, for example boron for a p-type field effect transistor FET (NFET) and phosphorus for a n-type FET (PFET).

A stack of semiconductor layers 102, including alternately formed first semiconductor layers 102a and second semiconductor layers 102b, is formed on the substrate 100. The first semiconductor layers 102a and the second semiconductor layers 102b are made of semiconductor materials having different etch selectivity and/or oxidation rates. For example, the first semiconductor layers 102a may be made of Si and the second semiconductor layers 102b may be made of SiGe. In some examples, the first semiconductor layers 102a may be made of SiGe and the second semiconductor layers 102b may be made of Si. Alternatively, in some embodiments, either of the semiconductor layers 102a and 102b may be or include other materials such as Ge, SiC, GeAs, GaP, InP, InAs, InSb, GaAsP, AlInAs, AlGaAs, InGaAs, GaInP, GalnAsP, or any combinations thereof. In the embodiment as shown in FIG. 1, the first semiconductor layers 102a are made of Si and the second semiconductor layers 102b is made of Si₁₋ₓGeₓ with x ranging between about 25% and about 50%.

The first semiconductor layers 102a or portions thereof may form channel(s) of the semiconductor device structure 102 in subsequent fabrication stages. The channels may be formed with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The channel(s) of the semiconductor device structure 10 may be surrounded by a gate electrode. The semiconductor device structure 10 may include a transistor with a nanoscale. The transistors with the nanoscale may be referred to as nanowire transistors, gate-all-around (GAA) transistors, multi-bridge channel (MBC) transistors, or any transistors having the gate electrode surrounding the channels. The use of the first semiconductor layers 102a to define a channel or channels of the semiconductor device structure 10 is further discussed below.

The first and second semiconductor layers 102a and 102b may be formed by any suitable deposition process, such as epitaxy. For example, epitaxial growth of the layers of the stack of semiconductor layers 102 may be performed by a molecular beam epitaxy (MBE) process, a metalorganic chemical vapor deposition (MOCVD) process, and/or other suitable epitaxial growth processes.

The semiconductor layers 102a may define the channels of an FET, such as a n-type FET (NFET) or the channels of a second FET, such as a p-type FET (PFET). The thickness of the first semiconductor layers 102a is chosen based on device performance considerations. In some embodiments, each semiconductor layer 102a has a thickness ranging from about 3 nanometers (nm) to about 10 nm. The second semiconductor layers 102b may eventually be removed and serve to define spaces for a gate stack to be formed therein. Likewise, each of the second semiconductor layers 102b may have a thickness that is equal to, less than, or greater than the thickness of the first semiconductor layers 102a, depending on device performance considerations. In one embodiment, each second semiconductor layers 102b has a thickness that smaller than the thickness of the semiconductor layers 102a.

In FIG. 1, the stack of semiconductor layers 102 includes four first semiconductor layers 102a and four second semiconductor layers 102b. It is appreciated that the numbers of the first and second semiconductor layers 102a and 102b in the stack of semiconductor layers 102 may vary depending on the desired number of channels with a nanoscale needed for the semiconductor structure 10. It is appreciated that the structure as shown in FIG. 1 may extend along the x-direction and/or the y-direction for forming an array of cell units on the substrate 10. The semiconductor structure 10 is applied to various devices such as a forksheet device which includes a PFET and an NFET arranged side by side at the same level along the y-direction. The semiconductor structure 10 may also be applied to a complementary FET (CFET) device in which an additional stack of semiconductor layers is formed over the stack of semiconductor layers 102 along the z-direction.

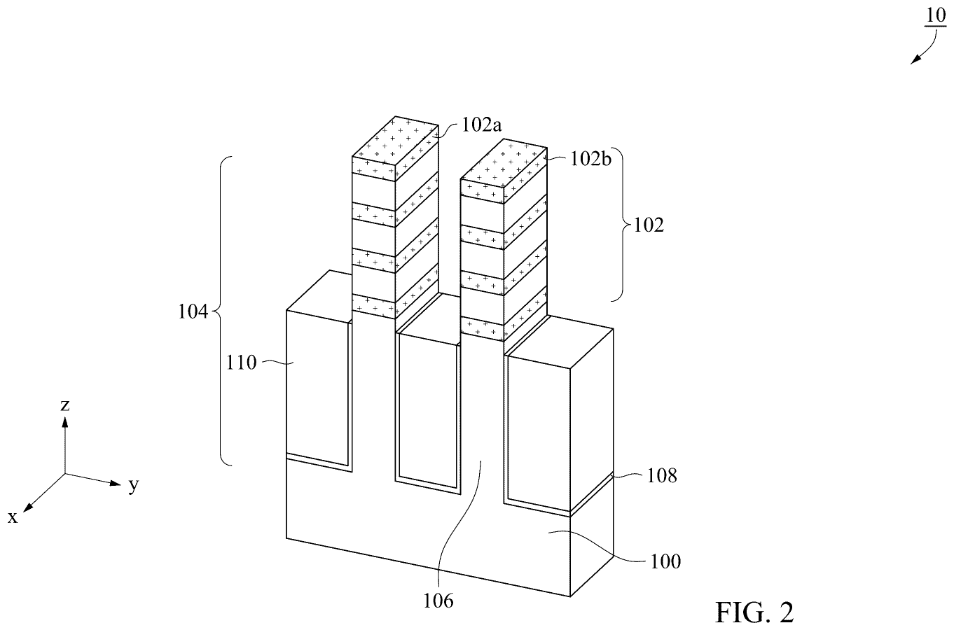

The stack of semiconductor layers 102 and a portion of the substrate 100 are then patterned to form into at least two semiconductor fins 104 as shown in FIG. 2. Each of the semiconductor fins 104 includes the well portion 106 formed by patterning the substrate 100 and one of the stacks of the semiconductor layers 102. To form the fin structures 104, a mask structure (not shown) may be formed on the stack of semiconductor layers 102. The mask structure may include an oxygen-containing layer and a nitrogen-containing layer. The oxygen-containing layer may be a pad oxide layer, such as a SiO₂ layer. The nitrogen-containing layer may be a pad nitride layer, such as Si₃N₄. The mask structure may be formed by any suitable deposition process, such as chemical vapor deposition (CVD) process or plasma enhance atomic layer deposition (PEALD).

A photoresist layer (not shown), for example, an oxide layer, is formed on the mask structure. The photoresist layer and the mask structure are then patterned to expose the underlying second semiconductor layers 102b of the stack of semiconductor layers 102. The photoresist layer may be formed by plasma enhance chemical vapor deposition (PECVD), for example. The exposed portions of the stack of semiconductor layers 102 are then removed until a predetermined thickness of the underlying substrate 10 is also removed. Each of the fin structures 104 may include the patterned stack of semiconductor layers 102 and a well portion 106 made from the substrate 10 under the patterned stack of semiconductor layers 102.

A conformal liner layer 108 may be formed over the substrate 100. That is, as shown in FIG. 2, the liner layer 108 is formed to cover the exposed surfaces of the well portions 106 and the exposed top surface of the substrate 10. In some embodiments, the liner layer 108 may be made of the same material as the substrate 100. The liner layer 108 may be formed by any suitable process, such as an atomic layer deposition (ALD) process. The term “conformal” may be used herein for ease of description upon a layer having substantial same thickness over various regions. The liner layer 108 may be made of silicon nitride, silicon oxynitride SiON, SiOCN, SiCN, fluorine-doped silicate glass (FSG), a low-k dielectric material, or any suitable dielectric material.

After formation of the liner layer 108, an insulating material 110 is formed on the substrate 100. The insulating material 110 partially fills the portions of the trenches at both sides of each semiconductor fin structure 104. For example, the insulating material 110 fills the portions between the neighboring well portions 106 of the corresponding semiconductor fins 104. In some embodiments, the insulation material 110 may be formed by suitable processes such as thermal oxidation to serve as shallow trench isolation (STI) with a top surface slightly lower than the top surface of the well portions 106. The mask structure and the photoresist layer are then removed to expose the stack of semiconductor layers 102.

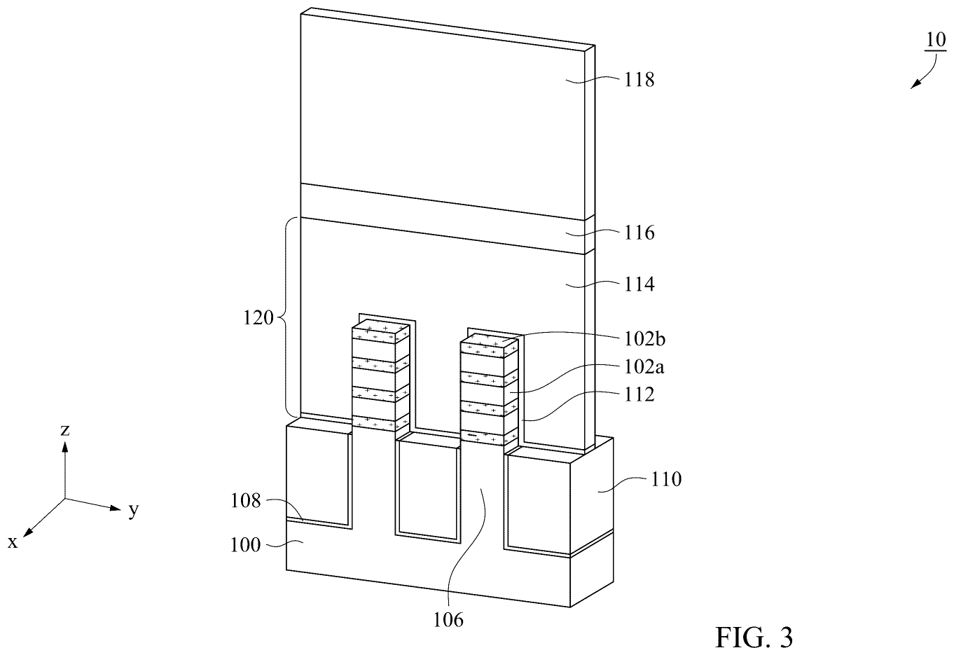

FIG. 3 shows the process of forming the dummy gate structure. As shown, a conformal sacrificial dielectric layer 112 is formed on the exposed surfaces of the semiconductor structure 10, including the exposed surfaces of the STI 110 and the stack of semiconductor layers 102. The sacrificial dielectric layer 112 may include an oxide layer formed by flowable deposition such as flowable chemical vapor deposition (FCVD) or other suitable processes. A sacrificial gate electrode layer (or a dummy gate electrode layer) 114 is formed over the sacrificial dielectric layer 112 and filling the trenches between the stack of semiconductor layers 102. The dummy gate electrode layer 114 may be an amorphous silicon or polysilicon layer deposited by CVD, low pressure CVD (LPCVD), plasma-enhanced CVD (PECVD), Physical vapor deposition (PVD), ALD, sputter deposition, or other suitable deposition processes. A hard mask layer 116 is then formed over the dummy gate electrode layer 114. The hard mask layer 116 may be a nitrogen-containing layer such as silicon nitride, silicon oxide, silicon carbon-nitride, or multi-layers thereof. The mask layer 116 may be formed by PEALD or other suitable deposition processes.

Further in FIG. 3, a resist layer 118 is formed to pattern the hard mask layer 116, the sacrificial gate electrode layer 114, and the sacrificial gate dielectric layer 112. In one embodiment, the resister layer 118 may include an oxide layer formed by PEALD or other suitable processes. The dummy gate electrode layer 114 and the sacrificial gate dielectric layer 112 are then patterned using acceptable photolithography and etching techniques with the resist layer 118 as a mask. The resist layer 118 is removed after the sacrificial dielectric layer 112, the dummy gate electrode layer 114 and the hard mask layer 116 are patterned into a plate-like structure extending along the y-z plane. As shown in FIG. 3, the dummy gate structure 120 (including the sacrificial dielectric layer 112 and the patterned dummy gate electrode layer 114) and the hard mask 116 extends across the stack of semiconductor layers 102 along the y-direction.

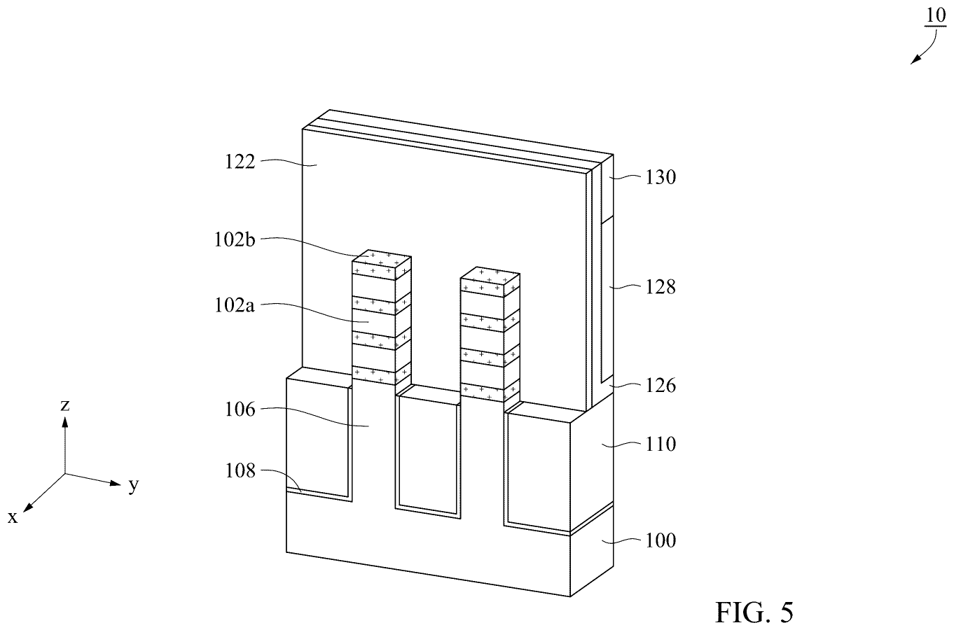

A gate spacer layer (122 as shown in FIG. 5) is formed on two opposite sidewalls of the dummy gate structure 120. In some embodiments, the gate spacer layer 122 may be formed of dielectric material such as Si₃N₄ layer formed by flowable CVD, ALD, or other suitable deposition processes. The gate spacer layer 122 may include a single-layer or multi-layer structure made of multiple dielectric layers. An etch process is then performed to remove the portions of the stacks of semiconductor layers 102 uncovered by the dummy gate structure 120. The exposed portions of the stacks of semiconductor layers 102 may be removed by an anisotropic until the underlying well portions 106 are exposed.

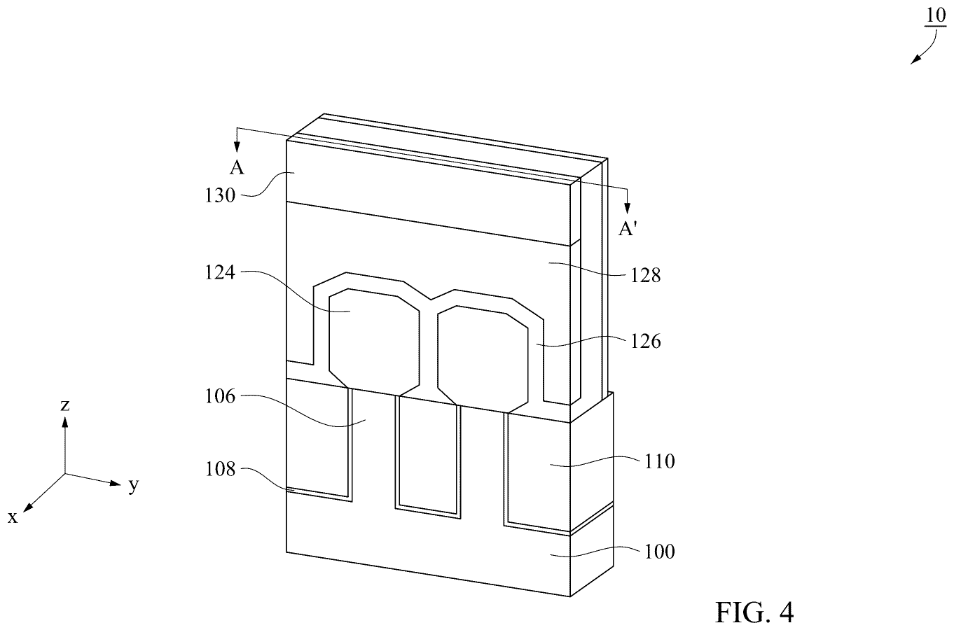

In FIG. 4, epitaxy regions, that is, source/drain regions, 124 are formed on the exposed well portions 104. Source/drain regions 124 may include silicon germanium SiGe or silicon Si. Depending on the conductive type of the FET to be formed, a p-type or an n-type dopant may be introduced with the epitaxy growth of the source/drain regions 124. For example, when a PFET is formed, silicon germanium boron SiGeB may be epitaxially grown. Alternatively, silicon phosphorous SiP or silicon carbon phosphorous SiCP may be epitaxially grown when an NFET is formed. In some embodiments, the source/drain regions 124 may be formed of a III-V semiconductor compound such as GaAs, InP, GaN, InGaAs, InAlAs, GaSb, Alsb, AlAs, AIP, GaP, or a combination or multilayer thereof. After the epitaxial growth, the source/drain regions 124 may be further implanted with a p-type or an n-type impurity. In some embodiments, the impurity implantation may be in-situ doped during the epitaxy growth of the source/drain regions 124. In the embodiment as shown in FIG. 4, an NFET may be formed with the S/D 124, and a PFET may be formed with the S/D 124.

Further in FIG. 4, a contact etch stop layer (CESL) 126 is conformally formed on the source/drain regions 124, and an interlayer dielectric (ILD) 128 is formed over the CESL 126. The CESL 126 may be formed of silicon nitride, silicon carbo-nitride, or the similar materials. In some embodiments, the CESL 126 may be oxygen free and formed using a conformal deposition process such as ALD or CVD, for example. The ILD 128 may be formed of SiO₂ based dielectric materials such as tetra ethyl ortho silicate (TEOS), PECVD SiO₂, phosphor-silicate glass (BSG), boron-doped phosphor-silicate glass (BPSG), or the similar materials. In some embodiments, a hard mask layer 130 may be formed on the ILD 128. A planarization process such as chemical mechanical polish (CMP) process or a mechanical grinding process may be performed to level the top surface of hard mask layer 130, the gate spacer layer 122, and the dummy gate structure 120 as shown in FIG. 4.

FIG. 5 is a perspective view of the semiconductor device 10 extending along the y-z plane cut along the line A-A′ as shown in FIG. 4. As shown in FIG. 4, the line A-A′ extends along the y-direction between a pair of source/drain regions 124 formed at two opposite sides of the dummy gate structure 120. In FIG. 5, the hard mask layer 116 and the dummy gate structure 120 are removed to expose the remaining stack of semiconductor layers 102 extending between the pair of source/drain regions 124 at different positions in the y-direction.

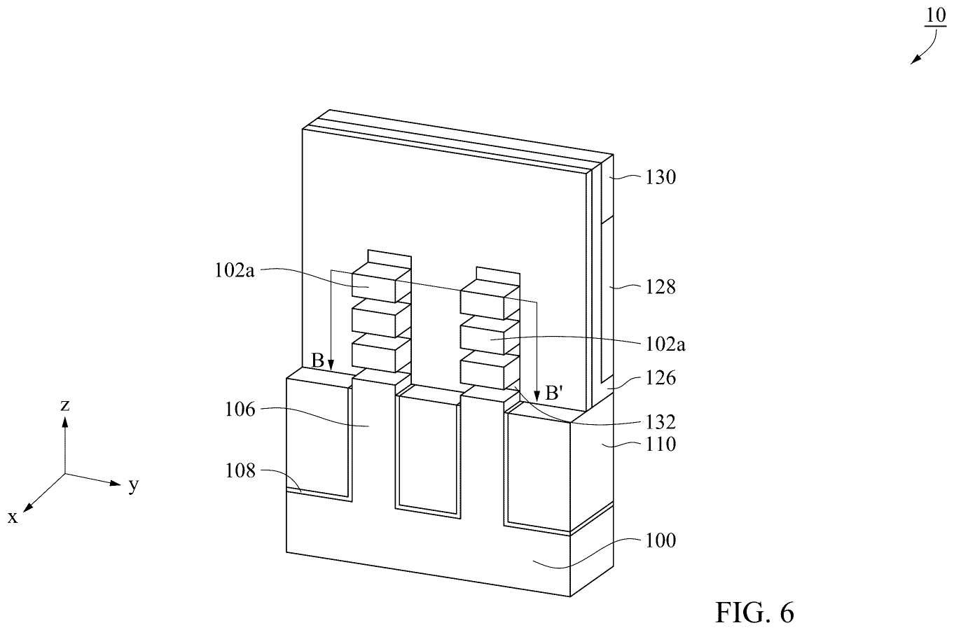

In FIG. 6, the second semiconductor layers 102b are removed, leaving the first semiconductor layers 102a to serve as channels. In some embodiments, before the semiconductor layers 102b are removed, the peripheral portions of each of the semiconductor layers 102b may be etched away to form cavities. The cavities may then be filled The inner spacer layer may comprise a material such as silicon nitride (SiN) or silicon oxynitride (SiON), although any suitable material, such as low-dielectric constant (low-k) materials having a k-value less than about 3.5, may be utilized. The inner spacer layer may then be etched to form the inner spacers. The inner spacer layer may be etched by an anisotropic etching process, such as RIE, NBE, or the like. The inner spacers may be used to prevent damage to subsequently formed source/drain regions 124 and 126 by subsequent etching processes.

The second semiconductor layers 102b may be removed by an etch process using etchant that can selectively etch the second semiconductor layers 102b in accordance with some embodiments. For example, the second semiconductor layers 102b made of SiGe may be selectively removed using a wet etchant such as ammonium hydroxide (NH₄OH), tetramethylammonium hydroxide (TMAH), ethylenediamine pyrocatechol (EDP), or potassium hydroxide (KOH) solution.

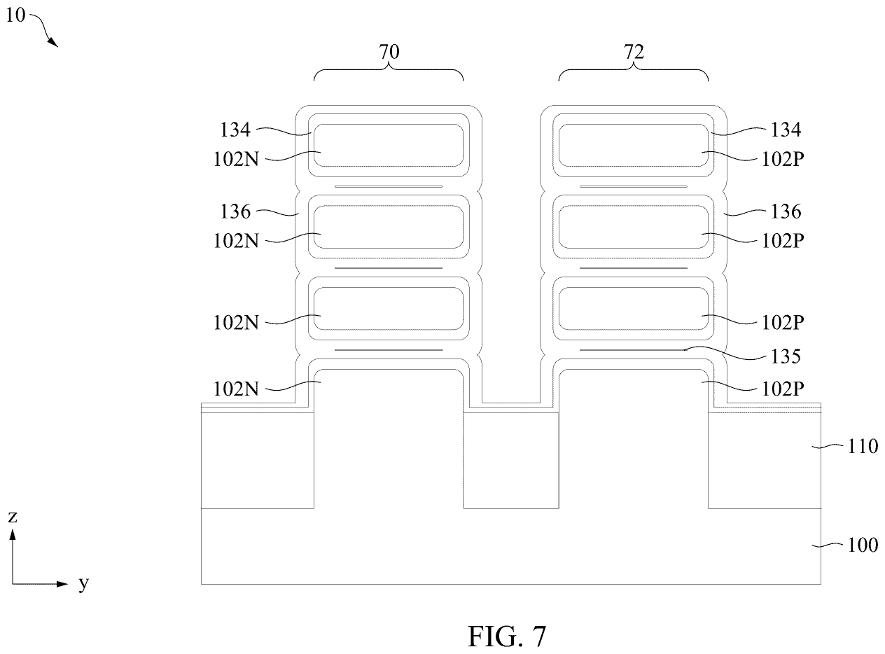

FIGS. 7-12 are cross-sectional views cutting along B-B′ of FIG. 6 to show the operation for forming metal gate material on the first semiconductor layers 102a of both the PFET and the NFET. According to some embodiments, one of the stacks of first semiconductor layers 102a may serve as the channel regions of an NFET 70, while the other of the stacks of first semiconductor layers 102a may serve as the channel regions of a PFET 72. The first semiconductor layers 102a serving as the channel regions of the NFET 70 are referred to as N-channels 102N, and first semiconductor layers 102a serving as the channel regions of the PFET 70 are referred to as P-channels 102P hereinafter. As shown in FIG. 7, a gate dielectric layer 134 is conformally formed to wrap around each of the P-channels 102P and the N-channels 102N. In some embodiments, the gate dielectric layer 134 may also be formed on the other exposed surfaces of the semiconductor device 10. For example, the gate dielectric layer 134 may be formed on the exposed surfaces of the exposed STI 110 and the well portion 106. The gate dielectric layer 134 may include one or multiple layers of high-k dielectric materials such as silicon oxide, silicon nitride, and/or a combination thereof. Examples of the high-k dielectric materials may also include, but not limited to, HfO₂, HfSiO, HfSiON, HfTaO, HfTiO, zirconium oxide, aluminum oxide, titanium oxide, hafnium dioxide-alumina (HFO₂-AlₓO₃) alloy, or other suitable high-k materials. The gate dielectric layer 134 may be formed by CVD, ALD, or other suitable processes. In accordance with some embodiments, the gate dielectric layer 134 may be formed using a highly conformal deposition process such as ALD in order to ensure formation of a gate dielectric layer 134 having a uniform thickness around each of the N-channels 102N and P-channels 102P. The thickness of the gate dielectric layer 134 may range from about 1 nm to about 6 nm, for example.

After the gate dielectric layer 134 is formed, a first metal gate layer 136 is conformally formed on the P-channels 102P and the N-channels 102N and fills the spaces between immediately adjacent P-channels 102P. When the first metal gate layer 136 is intended for forming the metal gate film of the PFET 72, the first metal layer 138 may include a p-type work function metal (WFM) layer for the PFET 72. According to some embodiments, the first metal layer 136 may include aluminum (Al), zinc (Zn), indium (In), copper (Cu), indium copper (InCu), tin (Sn), tantalum (Ta), tantalum nitride (TaN), tantalum carbide (TaC), titanium (Ti), titanium nitride (TiN), titanium carbide (Ti), TiAlC, TiAl, tungsten (W), tungsten nitride (WN), tungsten carbide (TiC), polycrystalline silicon (poly-Si), and/or a combinations thereof. The first metal layer 136 may be formed by CVD, ALD, electro-plating, or other suitable processes. As shown in FIG. 7, the undesired voids and/or seams may be formed in the first metal gate layer 136 between the adjacent P-channels 102P and N-channels 102N.

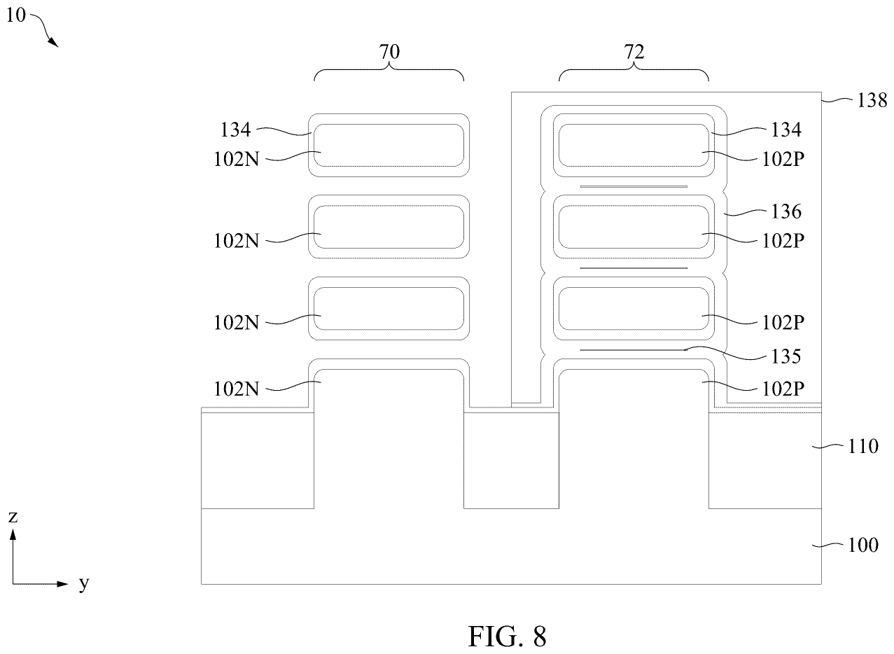

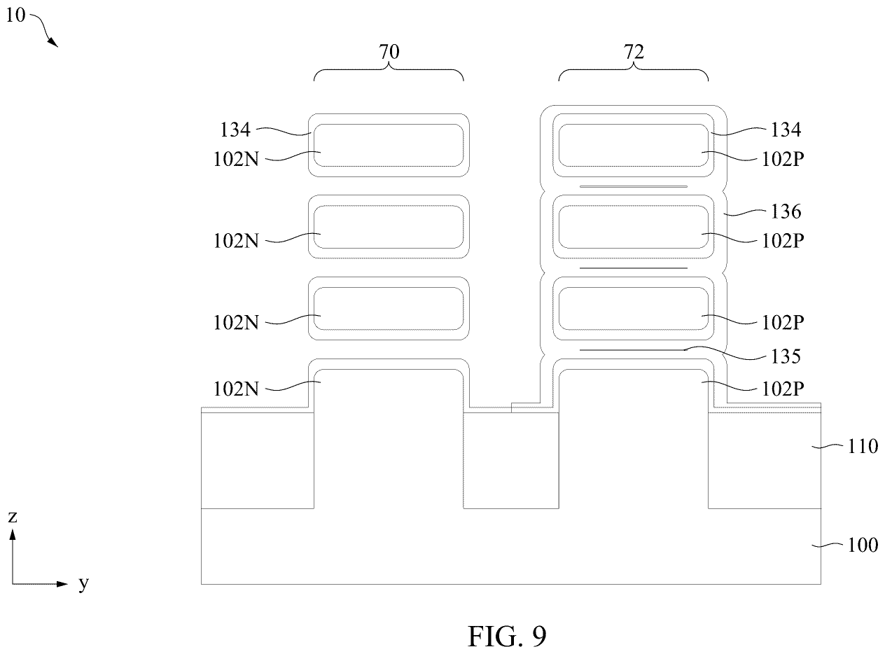

In FIG. 8, a mask layer 138 is formed to cover the P-channels 106P of the PFET 72 and expose the N-channels 102N of the NFET 70. The exposed first metal gate layer 136 around the N-channels 102N of the NFET 70 is then removed. According to some embodiment, the first metal gate layer 136 on the N-channels 102N may be removed by a wet etching process, for example, an RIE process or other suitable operations. The mask layer 138 is removed after the first metal gate layer 136 wrapping around the N-channels 102N has been removed as shown in FIG. 9.

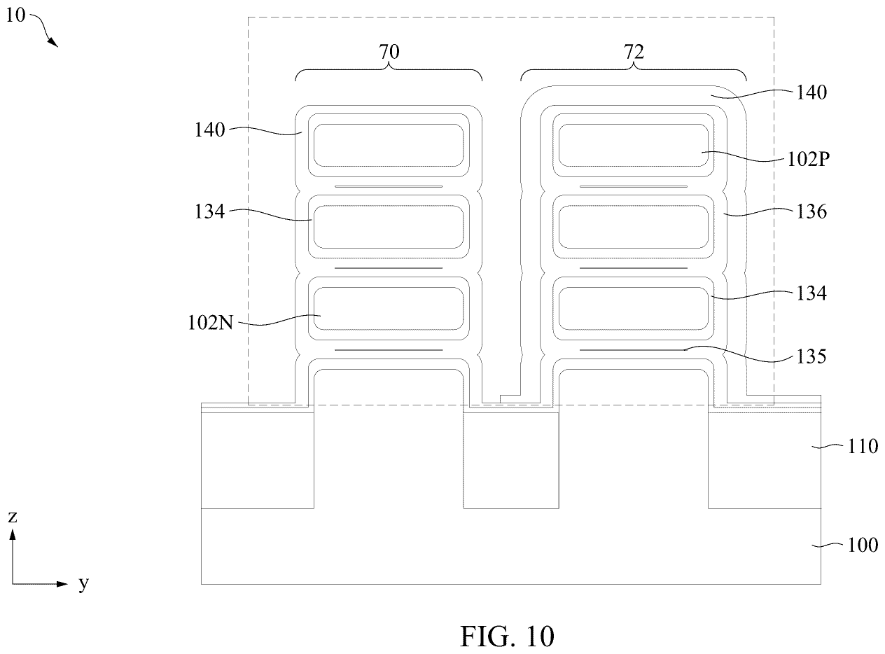

In FIG. 10, a second metal gate layer 140 is conformally formed on the exposed surfaces of the N-channels 102N and the first metal gate layer 136 covering the P-channels 102P. The second metal gate layer 140 fills the gaps, that is, sheet-to-sheet or channel-to channel space within the same FET (NFET), between each pair of immediately adjacent N-channels 102N. However, filling the very limited space of the gaps between the N-channels 102N is challenging as the material of the second metal gate layer 140 tends to merge at the edges before the central portion of the gaps is properly filled. The precursors used for forming the second metal gate layer 140 are thus hindered from entering into the central portion of the gap; and thus cause formation of voids and/or seams in the central portion of the gap. Formation of voids and seams may seriously impact the stability of threshold voltage V_{T}, and consequently affects production yields and degrades device performance. The same issues caused by formation of the voids and/or seams 135 may also occur to the first gate metal layer 136 formed on the P-channels 102P. However, as the threshold voltage V_{T} of PFET is often higher than that of NFET, the impacts are not as significant as those occurring to NFET.

To minimize formation of voids and/or seams at the sheet-to-sheet space, according to some embodiments, materials such as Ti, Ta, TiC, TiSi, Nb, Zr, or other metals or conductive materials added with Al-based material are used for forming the second metal gate layer 140. The Al-based material may include triethylaluminum (TEA), trimethylaluminum (TMA), triisobutylaliminum TTiBA), tris(tert-butyl) aluminum (TtBA), or other organoaluminum precursors. An atomic layer deposition (ALD) process may be used for forming the second metal gate layer 140. After the ALD process, a post thermal treatment may be performed according to some embodiments. In addition to the metals and Al-based materials, the second metal gate layer 140 may also be doped with Si, N, F, P and C.

According to some embodiment, when TiAlC is formed to serve as a portion of the second metal gate layer 140, titanium tetrachloride (TiCl₄) may be used as a first precursor introduced into the reaction chamber for performing the ALD process. The TiCl₄ is a colorless liquid with molecular weight of 189.69, a boiling point at about 137°, and a melting point at about −24° C. With a first pulse is applied (TiCl₄ pulse), the TiCl₄ may react with the dangling O—H bond on the exposed surface of the N-channels 102N to generate HCl and to bond with the N-channels 102N as —O—TiCl₃. The reaction of with application of the TiCl₄ pulse may be presented as:

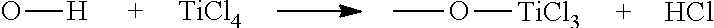

The gaseous HCl created in the ALD reaction chamber is then purged away by first purge operation. A second precursor is then introduced into the ALD reaction chamber. The second precursor may include Al-based material such as triethylaluminum TEA (C₆H₁₅Al) with a molecular weight of 114.17, a boiling point at about 128° C., and a melting point at about −46° C. The chemical structure of C₆H₁₅Al may include Al bonded with three C₂H₅. When a second pulse (TEA pulse) is applied, the reaction between the C₆H₁₅Al and the —O—TiCl₃ created during the TiCl₄ pulse may generate Ti—CH₂-Al and Ti—CH₂-Al for forming another component of the second metal gate layer 140 and byproducts of HCl and CH₃Cl. The reaction may be presented by:

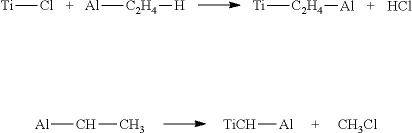

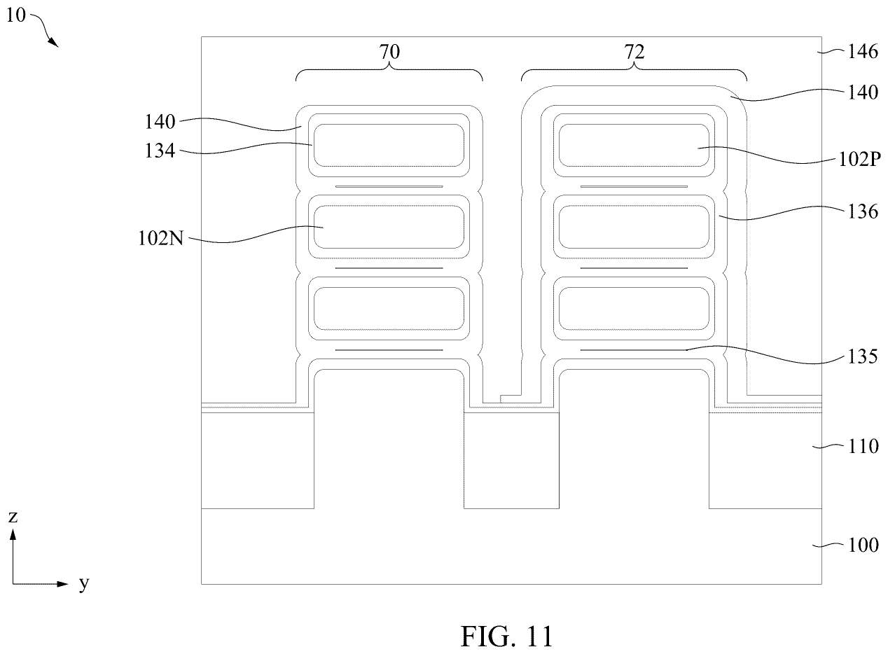

Other types of byproducts, such as gaseous CH₄, C₂H₄, and H₂, may also be generated during the application of TEA pulse. The byproducts are then purged away in a second purge operation. The TiCl₄ pulse operation, the first purge operation, the TEA pulse operation, and the second purge operation may be referred to one cycle. The same cycle may be repeated until the second metal gate layer 140 is formed and fills the gaps between each pair of adjacent N-channels 102N. At each cycle, the temperature may be controlled around 350° C. The TiCl₄ pulse operation may be performed for a duration of about 4 sec, and the TEA pulse operation may last for about 10 sec. The operation durations may vary depending on the electric performance of the device. The operation temperature may also vary when other types of first precursors are used for forming the second metal gate layer 140. According to some embodiments, the second metal gate layer 140 may be formed by performing multiple cycles, for example about 10 cycles. According to specific deposition conditions and the dimension of the gap between the adjacent N-channel 102N. More or less than 10 cycles may be required to form the second metal gate layer 140. Similar to the first metal gate layer 136, the second metal gate layer 140 may serve as a work function metal layer. After the formation of the second gate metal layer 140, a third metal gate layer 146 is formed as shown in FIG. 11.

After the third metal gate electrode 146 is formed, the process is approaching the end of the front-end-of-the-line (FEOL) operation where active devices and a desired number of passive devices are formed. Other structures such as the conductive features for interconnecting S/D regions and gates may be formed. At the end of the FEOL operation or other process stage after the second metal gate layer 140 has been formed, a post thermal treatment, for example, an anneal process, is performed to cause reflow of the Al-based materials formed by the ALD process. In the reflow may cause recrystallization of the Al-based materials, and the re-crystalline Al-based materials, for example, Al-based compound, for example, AlN, AlC, AlO, or other aluminum-based compound may diffuse towards the central portion of the gaps between the adjacent N-channels and to fill voids or seams that may have been formed during the ALD process for forming the second metal gate layer 140. The anneal process may include applying a laser spike for a few milliseconds, for example, about 5 milliseconds (msec) at a temperature of about 1150° C.

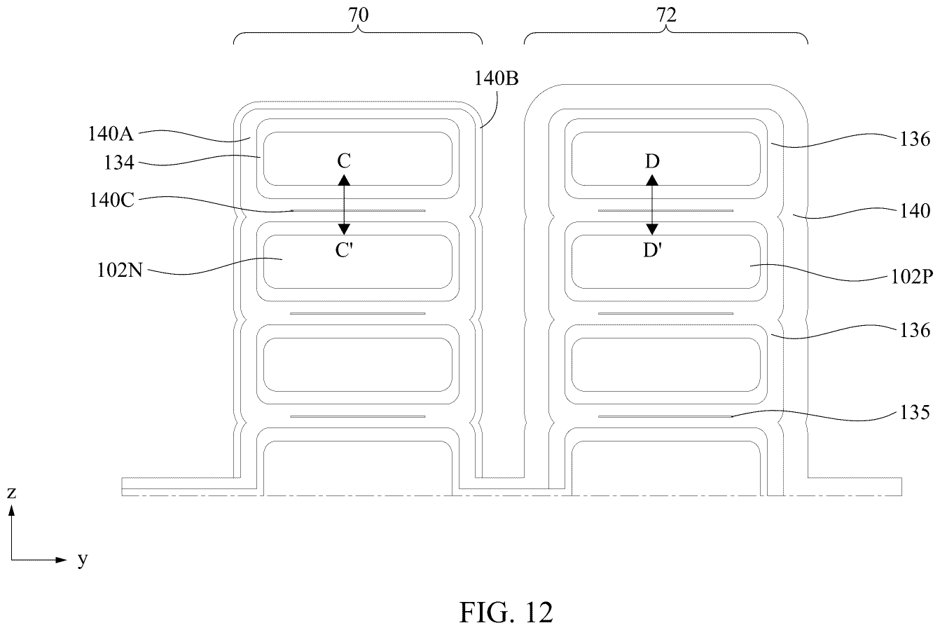

FIG. 12 is an enlarged cross-sectional view of the N-channels 102N and the second metal gate layer 140 extracted from the portion within the dash-line of FIG. 10. The second metal gate layer 140 may include a first Al compound layer such as a TiAlC layer 140A, a conformal TiN layer 140B on the TiAlC layer 140A and a second Al compound layer formed by Al-based compounds 140C such as AlN, AlC, AlO distributed in the gap between each pair of adjacent N-channels 102N. The Al-based compounds are re-distributed towards the central portion of the gaps by the thermal treatment as discussed above, such that voids and/or seams created during the ALD process may be filled by the Al-based compounds. In the embodiment as shown in FIG. 12, the Al-based compounds 140C is redistributed like an elongate layer extending laterally through the gap. According to some embodiment, the second metal gate layer 140 may include about 18% to 20% of Al, 10% to 13% of Ti, 14% to 17% of C, and 40% to 44% of O.

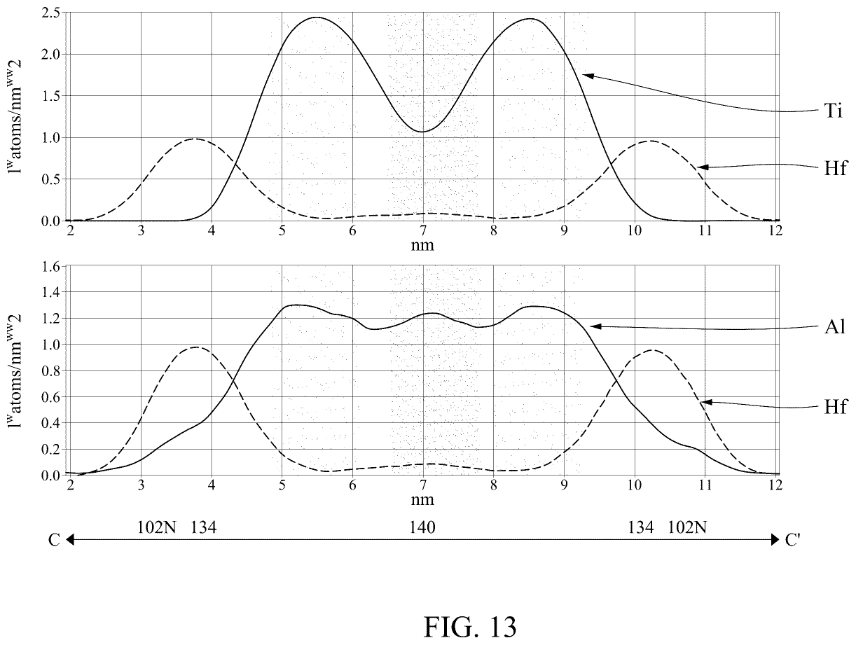

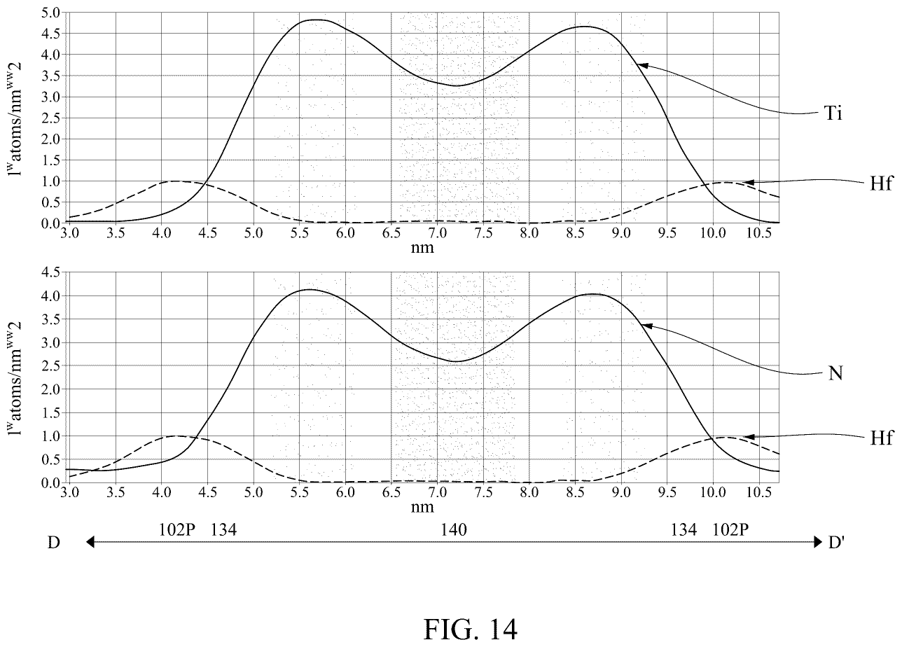

At the early operation stage for forming the channels 102a and 102b, a disposable oxide interposer (DOI) process may be used to mitigate the tensile strain and to avoid interfusion between the first semiconductor layers 102a and the second semiconductor layers 102b. As a result of the DOI process, the corners of the first semiconductor layers 102a are sharper, and the thickness between the immediately adjacent N-channels 102N is more uniform. As the thickness at the opening area is as narrow as that at the central portion, the gap-filling effect of the metal gate layer between the N-channels 102N is more challenging. The above-discussed ALD process and the post thermal treatment are specifically advantageous for forming the metal gate layer in the NFET that is formed using the DOI process. FIG. 13 shows the concentration distribution of Ti and Al from an electric energy loss (EEL) spectra taken across the second metal gate layer 140 between two adjacent N-channels 102N, for example, the portion cutting from C to C′ as shown in FIG. 12, according to some embodiments. FIG. 14 shows the first metal gate layer 136 between two adjacent P-channels 102P of the PFET 72. As shown in FIG. 13, at the central portion, the concentration of Ti drops to about 60%, while the concentration of Al drops under about 10%. This indicates that the central portion is filled by the Al-based compounds. That is, a significant amount of Al is distributed at the central portion of the gap between the adjacent N-channels 102N after the post thermal treatment. As a result, the voids and/or seams formed in the gap are filled by the Al-based compound. In contrast, as shown in FIG. 14, the concentrations of both Ti and N drops under about 40%, indicating a seam is formed in the central portion.

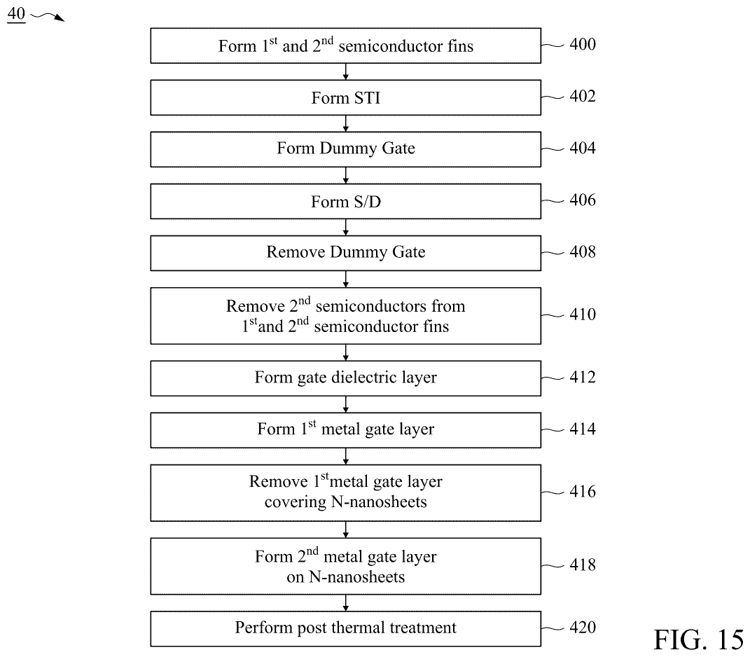

FIG. 15 shows a method 40 of forming a metal gate layer of a gate-all-around NFET. The method 40 includes several operations which will be described with reference to the embodiments as shown in FIGS. 1-12. At operation 400, a first semiconductor fin and a second semiconductor fin such as the semiconductor fins 102 as shown in FIG. 2 are formed on the respect well portions 106. Each of the first and second semiconductor fins includes a first semiconductor layers 102a and second semiconductor layers 102b alternately stacked with each other. According to some embodiments, the semiconductor first layers 102a may define the channels of GAAFETs. For example, the first semiconductor layers 102a of the first and second semiconductor fins may define channels of an NFET and a PFET, respectively.

At operation 402, STIs 110 are formed between the neighboring well regions 106 as shown in FIG. 2. In some embodiments, the insulation material 110 may be formed by suitable processes such as thermal oxidation to serve as shallow trench isolation (STI) with a top surface slightly lower than the top surface of the well portions 106. The mask structure and the photoresist layer are then removed to expose the stack of semiconductor layers 102.

At operation 404, a dummy gate structure is formed. For example, as shown in FIG. 3, the dummy gate structure 120 that includes the gate dielectric layer 112 and the sacrificial gate electrode 114 are formed with a plate-like structure extending along the x-z plane. At operation 406, epitaxy regions such as S/D regions 124 and 126 as shown in FIG. 4 are formed. According to some embodiments, n-type dopants and p-type dopants may be introduced with the epitaxy growth of the S/D region 124 and the S/D region 126, respectively.

After the S/D regions 124 and 126 are formed, the dummy gate structure 120 is removed at operation 408 to expose the first and second semiconductor fins 102. At operation 410, the second semiconductor layers 102b are removed, leaving the first semiconductor layers 102a to serve as channels. As shown in FIGS. 6 and 7, the first semiconductor layers 102a of the first semiconductor fin serving as the channels of the NFET 70 may be referred to as the N-channels 102N, while the first semiconductor layers 102a of the second semiconductor fin serving as the channels of the PFET 72 may be referred as P-channel 102P according to some embodiments.

At operation 412, a gate dielectric layer 134 is conformally formed to wrap around each of the P-channels 102P and the N-channels 102N. The gate dielectric layer 134 may include one or multiple layers of high-k dielectric materials such as silicon oxide, silicon nitride, and/or a combination thereof. The gate dielectric layer 134 may be formed by CVD, ALD, or other suitable processes. In accordance with some embodiments, the gate dielectric layer 134 may be formed using a highly conformal deposition process such as ALD in order to ensure formation of a gate dielectric layer 134 having a uniform thickness around each of the N-channels 102N and P-channels 102P. The thickness of the gate dielectric layer 134 may range from about 1 nm to about 6 nm, for example.

At operation 414, and a first metal gate layer 136 is conformally formed on surfaces of the N-channels 102N and the P-channels 102P at operation 414 as shown in FIG. 7. The first metal layer 138 may include a p-type work function metal (WFM) layer for the PFET 72. According to some embodiments, the first metal layer 136 may include aluminum (Al), zinc (Zn), indium (In), copper (Cu), indium copper (InCu), tin (Sn), tantalum (Ta), tantalum nitride (TaN), tantalum carbide (TaC), titanium (Ti), titanium nitride (TiN), titanium carbide (Ti), TiAlC, TiAl, tungsten (W), tungsten nitride (WN), tungsten carbide (TiC), polycrystalline silicon (poly-Si), and/or a combinations thereof. The first metal layer 136 may be formed by CVD, ALD, electro-plating, or other suitable processes.

At operation 416, the first metal gate layer 136 around the N-channels 102N is removed as shown in FIG. 9. The removal process may include a wet etching process such as an RIE operation. While removing the first metal gate layer 136 covering the N-channels 102N, referring to FIG. 8, a mask layer 138 may be formed to cover the PFET 72. The mask layer 138 is then removed, followed by the operation 418 for forming a second metal gate layer.

Referring to FIG. 10, the second metal gate layer 140 is conformally formed on the exposed surfaces of the N-channels 102N and the first metal gate layer 136 of the P-channels 102P and fills the gaps between the immediately adjacent N-channels 102N (sheet-to-sheet spaces).

To minimize formation of voids and/or seams at the sheet-to-sheet space, according to some embodiments, materials such as Ti, Ta, TiC, TiSi, Nb, Zr, or other metals or conductive materials added with Al-based material are used for forming the second metal gate layer 140. The Al-based material may include triethylaluminum (TEA), trimethylaluminum (TMA), triisobutylaliminum TTiBA), tris(tert-butyl) aluminum (TtBA), or other organoaluminum precursors. An atomic layer deposition (ALD) process may be used for forming the second metal gate layer. After the ALD process, a post thermal treatment may be performed according to some embodiments.

According to some embodiments, the metal material such as Ti, Ta, TiC, TiSi, Nb, Zr, or other metals or conductive materials may be used as the first precursor for the deposition process, and the Al-based material may be used as the second precursor for the deposition process. A pulse is applied when each of the first and second precursors is introduced into the deposition chamber. Byproducts created during each pulse operation may be purged away. According to some embodiments, the deposition process may be performed by more or less than 10 cycles, and each cycle includes a first pulse operation applied to the first precursor, a first purge operation, a second pulse operation applied to the second precursor, and a second pulse operation. When TiAlC is formed as the major component of the second metal gate layer 140, titanium tetrachloride (TiCl₄) may be used as a first precursor, and TEA may be used as the second precursor. The deposition process such as the ALD process is performed with an operation temperature of about 350° C.

At operation 420, a post thermal treatment is performed. The post thermal treatment may include an anneal process when the fabrication the process is approaching the end of the front-end-of-the-line (FEOL) operation where active devices and a desired number of passive devices are formed. The anneal process may include applying a laser spike for a few milliseconds, for example, about 5 msec at a temperature of about 1150° C. to cause reflow of the Al-based materials created during the ALD process. In The reflow may cause recrystallization of the Al-based materials and caused the recrystallized Al-based compound, for example, AlN, AlC, AlO, or other aluminum-based compound to diffuse towards the central portion of the gaps between the adjacent N-channels and to fill voids or seams that may have been formed during the ALD process for forming the second metal gate layer 140.

According to one embodiment, a semiconductor device structure is provided. The semiconductor device structure comprises a first stack of channels of a p-type field effect transistor (PFET) and a second stack of channels of an n-type field effect transistors (NFET) adjacent to the PFET. A gate dielectric layer is formed on each channel of the PFET and the NFET. A first metal gate layer is formed on the gate dielectric layer of the PFET. A second metal gate layer is formed on the gate dielectric layer of the NFET. The second metal gate layer comprises one or more types of aluminum compounds filling at least a central portion of a channel-to-channel space between each pair of immediately adjacent channels of the NFET.

According to another embodiment, a semiconductor device structure is provided, comprising a stack of channels of an n-type field effect transistors (NFET), a high-k gate dielectric layer on each of the channels, and a metal gate layer on each channel. The second metal gate layer comprises one or more types of aluminum compounds filling at least a central portion of a channel-to-channel space between each pair of immediately adjacent channels of the NFET and a metal-aluminum compound layer wrapping around each channel.

According to yet another embodiment, a method of forming a metal gate layer is provided. The method includes depositing the metal gate layer on each of a stack of channels of an NFET. The depositing process comprises introducing a first precursor and applying a first pulse, the first precursor comprising metal compounds, purging byproducts formed during application of the first pulse, introducing a second precursor and applying a second pulse, the second precursor comprising aluminum-based materials, and purging byproducts formed during application of the second pulse.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a first stack of channels of a first transistor;
a second stack of channels of a second transistor adjacent to the first transistor;
a gate dielectric layer formed around each channel of the first transistor and the second transistor;
a first metal gate layer on the gate dielectric layer of the first transistor; and
a second metal gate layer on the gate dielectric layer of the second transistor, wherein the second metal gate layer comprises aluminum compound layers disposed between immediately adjacent channels of the second transistor.

2. The semiconductor structure of claim 1, wherein a first of the aluminum compound layer include AlO, AlC, AlN.

3. The semiconductor structure of claim 1, wherein the first aluminum compound layer extending in parallel with and between immediately adjacent channels of the second transistor.

4. The semiconductor structure of claim 1, wherein a second of the aluminum compound layers wraps around each channel of the second transistor.

5. The semiconductor structure of claim 4, wherein the second aluminum compound layer is a TiAlC layer.

6. The semiconductor structure of claim 4, wherein a TiN layer coated on the second aluminum compound layer.

7. The semiconductor structure of claim 1, wherein the first metal gate layer is covered by the second metal gate layer.

8. A semiconductor structure, comprising:
a stack of channels of an n-type field effect transistors (NFET);
a high-k gate dielectric layer on each of the channels; and
a metal gate layer on the gate dielectric layer, wherein the metal gate layer comprises:
one or more types of aluminum compounds filling at least a portion of a space between immediately adjacent channels of the NFET; and
a metal-aluminum compound layer wrapping around each channel.

9. The semiconductor structure of claim 8, wherein the aluminum compounds include AlO, AlC, AlN.

10. The semiconductor structure of claim 8, wherein the metal-aluminum compound layer comprises TiAlC.

11. The semiconductor structure of claim 8, wherein the aluminum compounds form a layer disposed in parallel with and between the channel-to-channel space.

12. A method, comprising:
depositing a metal gate layer around each of a plurality of channels stacking over each other, comprising:
introducing a first precursor and applying a first pulse, wherein the first precursor comprises metal compounds;
purging first byproducts formed during application of the first pulse;
introducing a second precursor and applying a second pulse, wherein the second precursor comprises aluminum-based materials; and
purging second byproducts formed during application of the second pulse; and
performing a thermal treatment.

13. The method of claim 12, wherein the first precursor comprises Ti halide, Ta halide, Hf halide, Nb halide, and Zr halide.

14. The method of claim 12, wherein the aluminum-based materials comprises Trimethylaluminum (TMA), Triethylaluminum (TEA), Triisobutylaluminum (TiBA), Tris(tert-butyl) aluminum (TtBA), and other Organoaluminium precursors.

15. The method of claim 12, wherein the first byproducts formed by introducing the first precursor and applying the first pulse comprise HCl.

16. The method of claim 12, wherein the second byproducts formed by introducing the second precursor and applying the second pulse comprise HCl, CH₄, C₂H₄, and H₂.

17. The method of claim 12, further comprising performing a plurality of cycles for depositing the metal gate layer, and each cycle comprising:
introducing the first precursor and applying a first pulse, the first precursor comprising metal compounds;
purging byproducts formed during application of the first pulse;
introducing the second precursor and applying a second pulse, the second precursor comprising aluminum-based materials; and
purging byproducts formed during application of the second pulse.

18. The method of claim 12, wherein the first pulse is applied for about 4 seconds, and the second pulse is applied for about 10 seconds.

19. The method of claim 12, wherein the thermal treatment includes an annealing process at an annealing temperature of about 1150° C. for about 5 msec.

20. The method of claim 12, further comprising:
forming aluminum-based compounds by introducing the second precursor and applying the second pulse; and
filling voids, seams, or both of voids and seams, formed between adjacent channels by performing the thermal treatment.
